(19) United States
(12) Patent Application Publication
(10) Pub. No.: US 2012/0049241 A1
(43) Pub. Date: Mar. 1, 2012

(54) CDM-resilient high voltage ESD protection cell

(75) Inventor: Vladislav Vashchenko, Palo Alto, CA (US)

(73) Assignee: National Semiconductor Corporation

(21) Appl. No.: 12/807,107

(22) Filed: Aug. 27, 2010

(51) Int. Cl. H01L 27/06; H01R 43/00

(52) U.S. Cl. 257/146; 29/825; 361/56; 257/E27.024

(57) ABSTRACT

In a high voltage ESD protection structure with a gate voltage reference and low impedance load, the CDM robustness of the structure is improved by including a gate resistor and a reverse path diode.

### FIELD OF THE INVENTION

The invention relates to Electrostatic Discharge (ESD) protection. In particular it relates to protection against high speed pulses as defined by the charged device model (CDM).

### BACKGROUND OF THE INVENTION

In order to control the turn-on of high voltage electrostatic discharge (ESD) protection clamps, the control gates of the clamps are commonly controlled using a voltage reference such as an avalanche diode connected between the high voltage pad and the control gate, as shown in FIG. 1, which shows an NLDMOS-SCR 100 with gate 102 connected to a voltage reference defined by avalanche diode 104 connected to the gate 102 and to ground via resistor 106.

However, while these devices work well for relatively low frequency pulses such as the 100 ns human body model (HBM) pulses, this is not the case with very fast TLP (of the order of 2 ns), as defined by the charged device model (CDM) pulse. In the case of CDM pulses, these clamps demonstrate low passing levels. This is especially the case when the ESD clamp is protecting circuits with low internal loads.

### SUMMARY OF THE INVENTION

According to the invention there is provided a CDM-resilient high voltage (electrostatic discharge) ESD protection structure connected to a high voltage node, comprising an ESD clamp that includes a control gate, an avalanche diode connected between the high voltage node and the control gate to define a gate voltage reference, and a gate resistor connected between the gate voltage reference and the control gate.

The structure may further comprise a capacitor connected between the control gate and ground. The capacitor may be defined by a reverse path diode. The structure may include a ground path resistor between the gate voltage reference and ground, and the reverse path diode may be connected in parallel to the ground path resistor.

Further, according to the invention, there is provided a method of avoiding CDM stress damage in an ESD clamp with high side high voltage avalanche diode reference providing a voltage reference to a control gate of the ESD clamp, comprising providing the control gate with a resistor between the control gate and the avalanche diode reference, to reduce the voltage to the control gate. The method may comprise connecting a reverse path diode between the control gate and ground.

The voltage reference may include a resistor connected between the avalanche diode reference and ground.

Still further, according to the invention, there is provided an ESD clamp with CDM resilience and reverse path protection comprising an ESD clamp that includes a control gate, a gate voltage reference that includes an avalanche diode and a resistor connected in series between a high voltage node and ground, the control gate being connected to a reference node between the avalanche diode and the resistor, and a reverse diode connected in parallel with the resistor between ground and the control gate. The clamp may include a second resistor between the reference node and the control gate.

### BRIEF DESCRIPTION OF THE DRAWINGS

FIG. 1 is a circuit diagram of a prior art ESD protection structure comprising an NLDMOS-SCR clamp with high side avalanche diode voltage reference,

FIG. 2 shows one embodiment of an ESD protection structure of the invention that includes an NLDMOS-SCR clamp with high side avalanche diode voltage reference and gate resistor, and

FIG. 3 shows another embodiment of an ESD protection structure of the invention that includes an NLDMOS-SCR clamp with high side avalanche diode voltage reference, as well as a gate resistor and a reverse path diode.

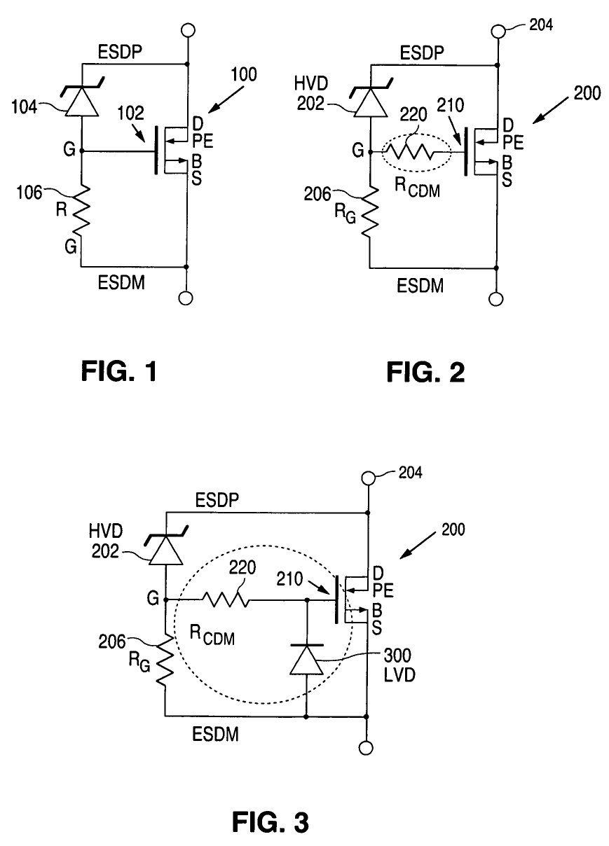

### DETAILED DESCRIPTION OF THE INVENTION

As mentioned above, high voltage ESD clamps operating with an avalanche diode reference have a high incidence of CDM failures when protecting pins with low internal loads. Failure analysis has shown gate-source region oxide damage, which suggests that the failure mechanism is gate-source breakdown in CDM pulse time domain. The dominant current path is related to the high side avalanche diode capacitance.

In particular, comparisons of the TLP and the very fast TLP (vfTLP) show significant differences in the clamping voltage due to the difference in the measurement time domain. Also, comparisons of vfTLP measurements made for clamps with and without a high side reference voltage component, show a three times higher gate current when a voltage reference component such as avalanche diode 202 is included.

The present invention therefore seeks, in particular, to address the high failure rates for ESD clamps with high side reference voltage under vfTLP conditions, especially when protecting pins with low internal loads.

FIG. 2 shows one embodiment of a clamp design that provides for greater CDM robustness. In this embodiment the clamp includes an NLDMOS-SCR 200 with high side gate reference in the form of avalanche diode 202 connected between the high voltage node 204 and the gate 210. The avalanche diode 202 is also connected to ground through ground path resistor 206. In accordance with the invention, a gate protection resistor 220 is included in the clamp, which has the effect of reducing the voltage seen by the gate 210.

Another embodiment of the invention is shown in FIG. 3, which is similar to the embodiment of FIG. 2 and therefore similar elements are numbered using the same reference numerals. In addition to the gate resistor 220, this embodiment provides for a reverse path diode 300. The reverse path diode 300 provides for additional capacitive load parallel to the node 204.

For the positive CDM current direction, the additional gate resistor 220 and additional load impedance due to the reverse path diode 300 have the effect of reducing the peak voltage presented to the gate 210.

The reverse path diode 300 also has the effect of improving robustness for negative ESD stresses in the CDM time domain. In the 100 ns TLP or HBM time domain the parasitic diode formed by the drain and bulk p−body or p+guard ring connection is sufficient for a reliable current path. However in the 2 ns TLP or CDM time domain the additional reverse diode is required. Thus the reverse diode 300 in the embodiment of FIG. 3 has the effect not only of reducing CDM failures during positive CDM stresses but also in the case of negative CDM stresses.

While the present application discusses two specific embodiments of the invention involving NLDMOS-SCR clamps and avalanche diode voltage reference, the present invention is not so limited but could be implemented using other clamps and gate voltage reference devices.

What is claimed is:

1. A CDM-resilient high voltage (electrostatic discharge) ESD protection structure connected to a high voltage node, comprising
an ESD clamp that includes a control gate,
an avalanche diode connected between the high voltage node and the control gate to define a gate voltage reference, and
a gate resistor connected between the gate voltage reference and the control gate.

2. A structure of claim 1, further comprising a capacitor connected between the control gate and ground.

3. A structure of claim 2, wherein the capacitor is defined by a reverse path diode.

4. A structure of claim 2, further comprising a ground path resistor connected between the gate voltage reference and ground.

5. A method of reducing CDM stress damage in an ESD clamp with high side high voltage avalanche diode reference that provides a voltage reference to a control gate of the ESD clamp, comprising
providing the control gate with a resistor between the control gate and the avalanche diode reference.

6. A method of claim 5, further comprising connecting a reverse path diode between the control gate and ground.

7. A method of claim 6, wherein the voltage reference includes a resistor connected between the avalanche diode reference and ground.

8. An ESD clamp with CDM resilience and reverse path protection, comprising
an ESD clamp that includes a control gate,
a gate voltage reference that includes an avalanche diode and a resistor connected in series between a high voltage node and ground, the control gate being connected to a reference node between the avalanche diode and the resistor, and
a reverse diode connected in parallel with the resistor between ground and the control gate.

9. An ESD clamp of claim 8, further comprising a second resistor between the reference node and the control gate.
